(19) United States
(12) Patent Application Publication
(10) Pub. No.: US 2026/0354249 A1
(43) Pub. Date: Nov. 5, 2026

(54) BONDING SCHEME TO PROVIDE IMPROVED COPLANARITY AND HIGH JOINT YIELDS WITH REDUCED COSTS AND METHODS FOR FORMING THE SAME

(71) Applicant: Taiwan Semiconductor Manufacturing Company Limited, Hsinchu (TW)

(72) Inventors: Kuan-Chung Pan, Hsinchu (TW); Ming-Che Ho, Tainan City (TW); Hung-Jui Kuo, Hsinchu (TW); Po-Yuan Teng, Hsinchu City (TW); An-Jhih Su, Taoyuan City (TW)

(21) Appl. No.: 19/738,381

(22) Filed: Jul. 11, 2026

Related U.S. Application Data
(62) Division of application No. 18/641,473, filed on Apr. 22, 2024.

(51) Int. Cl. H10W 72/90; H10B 80/00; H10W 20/20; H10W 70/05; H10W 70/65; H10W 70/652; H10W 70/654; H10W 70/66; H10W 72/00; H10W 72/20; H10W 90/00; H10W 90/20

(52) U.S. Cl. CPC H10W 72/90; H10W 72/012; H10W 72/019; H10W 72/072; H10W 72/20; H10B 80/00; H10W 20/20; H10W 70/05; H10W 70/65; H10W 70/652; H10W 70/654; H10W 70/66; H10W 72/01235; H10W 72/01935; H10W 72/07236; H10W 72/07255; H10W 72/221; H10W 72/222; H10W 72/232; H10W 72/244; H10W 72/247; H10W 72/248; H10W 72/252; H10W 72/2528; H10W 72/922; H10W 72/926; H10W 72/932; H10W 72/936; H10W 72/942; H10W 72/952; H10W 90/00; H10W 90/297; H10W 90/722

(57) ABSTRACT

Vertically stacked semiconductor devices and methods of fabrication thereof include intermediate redistribution layer (RDL) pads underlying a plurality of bump structures. A plurality of intermediate RDL pads may be formed over a first device structure, and at least one bump structure may be formed over each of the intermediate RDL pads. The bump structures include a metal layer and a barrier layer having a lower solder wettability located between the metal layer and the underlying intermediate RDL pad. The barrier layer may constrain solder wetting along the sidewall of the bump structure to minimize solder bridging and other defects. In some embodiments, the intermediate RDL pads may have a relatively lower solder wettability to minimize solder defects. Characteristics of the intermediate RDL pads and the bump structures may be controlled to improve the flatness characteristics of bump structures.

### RELATED APPLICATIONS

This application is a divisional of U.S. patent application Ser. No. 18/641,473, filed Apr. 22, 2024, entitled “Bonding Scheme to Provide Improved Coplanarity and High Joint Yields with Reduced Costs and Methods for Forming the Same,” the entire disclosure of which is incorporated herein by reference for all purposes.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a first semiconductor device structure according to various embodiments of the present disclosure.

FIG. 1B is a vertical cross-section view of the semiconductor device structure taken along line A-A′ in FIG. 1A.

FIG. 1C is a top view of a second semiconductor device structure according to various embodiments of the present disclosure.

FIG. 1D is a vertical cross-section view of the second semiconductor device structure taken along line B-B′ in FIG. 1C.

FIG. 1E is a vertical cross-sectional view illustrating the second semiconductor device structure aligned over the first semiconductor device structure according to various embodiments of the present disclosure.

FIG. 1F is a vertical cross-sectional view of a vertically stacked semiconductor device according to various embodiments of the present disclosure.

FIG. 2A is a vertical cross-sectional view illustrating a second semiconductor device structure aligned over a first semiconductor device structure according to another embodiment of the present disclosure.

FIG. 2B is a vertical cross-sectional view of a vertically stacked semiconductor device according to another embodiment of the present disclosure.

FIG. 3A is a vertical cross-sectional view illustrating a second semiconductor device structure aligned over a first semiconductor device structure according to another embodiment of the present disclosure.

FIG. 3B is a vertical cross-sectional view of a vertically stacked semiconductor device according to another embodiment of the present disclosure.

FIG. 4A is a vertical cross-sectional view illustrating a second semiconductor device structure aligned over a first semiconductor device structure according to another embodiment of the present disclosure.

FIG. 4B is a vertical cross-sectional view of a vertically stacked semiconductor device according to another embodiment of the present disclosure.

FIG. 5A is a top view of a first semiconductor device structure according to various embodiments of the present disclosure.

FIG. 5B is a vertical cross-section view of the first semiconductor device structure taken along line C-C′ in FIG. 5A.

FIG. 6 is a flowchart illustrating a method of fabricating a vertically stacked semiconductor device according to an embodiment of the present disclosure.

FIG. 7 is a flowchart illustrating a method of fabricating a vertically stacked semiconductor device according to another embodiment of the present disclosure.

FIG. 8 is a flowchart illustrating a method of fabricating a vertically stacked semiconductor device according to another embodiment of the present disclosure.

FIG. 9 is a flowchart illustrating a method of fabricating a bonding structure including an intermediate redistribution layer pad and a bump structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to vertically stacked semiconductor devices that include at least one semiconductor die stacked over and bonded to a second device structure. The second device structure may be, for example, another semiconductor die or a semiconductor wafer. The at least one semiconductor die may be vertically stacked in a configuration such as a system on integrated chip (SoIC), chip on wafer on substrate (CoWoS), chip on wafer (CoW), etc. Such vertically stacked semiconductor devices may increase the density of devices that may occupy a given planar area or “footprint.”

Semiconductor dies may include a semiconductor material substrate, such as a silicon substrate. The semiconductor material substrate may have a number of circuit components and elements formed on and/or within the semiconductor material. Semiconductor dies are typically fabricated by sequentially depositing insulating or dielectric layers, conductive layers, and semiconductive layers of material over a semiconductor substrate (e.g., a wafer), patterning the various material layers using lithography to form integrated circuits, and separating individual dies from the substrate such as by sawing (e.g., dicing) between the integrated circuits along scribe lines.

A vertically stacked semiconductor device may be formed by placing a semiconductor device structure onto another semiconductor device structure. The semiconductor device structures may be, for example, semiconductor dies, semiconductor wafers, or combinations thereof (e.g., a semiconductor die on a semiconductor wafer). A bonding process may be used to bond bonding structures on one semiconductor device structure to corresponding bonding structures on the other semiconductor device structure to form a vertically stacked semiconductor device.

In some embodiments, a microbump bonding technique may be used to bond the semiconductor device structures to form a vertically stacked semiconductor device. In such bonding techniques, an array of microbump structures, which may include metal (e.g., Cu) pillars having a solder cap, may be formed on a semiconductor device structure. The semiconductor device structure including the microbump structures may then be aligned with another semiconductor device structure, and the two semiconductor device structures may be brought into contact such that the microbump structures may contact corresponding bonding structures (e.g., metal pillars or bonding pads) on the other semiconductor device structure. A reflow process may then be used to form an electrical and mechanical bond between the two device structures.

In many cases, the vertically stacked semiconductor device will include different types of interconnections between the respective semiconductor device structures. For example, the vertically stacked semiconductor device may include a first set of one or more interconnections to provide die-to-die (D2D) communication bandwidth between the semiconductor device structures, and a second set of one or more interconnections for power delivery between the semiconductor device structures. These different types of interconnections may require different sizes (i.e., critical dimensions (CD)) of the bonding structures and/or different spacing (i.e., pitch) between the bonding structures used to bond the semiconductor device structures. Thus, a “hybrid” microbump technique may be used in which microbump structures having different critical dimensions (CD) and/or pitches to support different types of interconnections may be formed on a semiconductor device structure. However, a drawback to this approach is that forming the different types of microbump structures simultaneously (e.g., via an electrodeposition process) may produce microbump structures having a low degree of coplanarity, which can result in a poor joint window. Alternatively, the different types of microbump structures may be formed using separate deposition processes. This may help to improve the coplanarity issue, but it may add increased costs.

Another approach to a “hybrid” microbump technique is to form intermediate redistribution layer (RDL) pads on the semiconductor device structure, where the intermediate RDL pads have the desired pattern (e.g., different CDs and/or pitches) to support the various types of interconnections between the semiconductor device structures in the vertically stacked semiconductor device. Then, an array of microbump structures having a uniform CD and/or pitch may be formed over the intermediate RDL pads. This approach can help improve the coplanarity issue while also providing lower cost. However, it has been found that the use of intermediate RDL pads may still produce poor joint yields due to solder bridging, necking, and other defects. For example, it has been found that during the bonding process, there is a tendency for solder collapse and wetting of the underlying RDL pad, which can result in the occurrence of solder bridging between adjacent microbump structures. It has also been found that the microbump structures formed over the intermediate RDL pads may have an insufficient amount of flatness.

Various embodiments disclosed herein seek to overcome these drawbacks and may include vertically-stacked semiconductor devices, and methods of forming vertically-stacked semiconductor devices. The various embodiments disclosed herein may use “hybrid” microbump bonding structures including intermediate redistribution layer (RDL) pads underlying a plurality of bump structures that may provide improved bonding characteristics and device yields.

In some embodiments, a plurality of intermediate RDL pads may be formed over a first semiconductor device structure, and at least one bump structure may be formed over each of the intermediate RDL pads. The bump structures may have a uniform size and shape. The intermediate RDL pads may have variable sizes and/or shapes, and the number of bump structures that electrically contact different intermediate RDL pads may vary. Thus, such embodiments may facilitate transmission of different types of signals (e.g., power transmission, data transmission, etc.) between the first semiconductor device structure and a second semiconductor device structure in the vertically stacked semiconductor device. Each of the bump structures may include a metal layer and a barrier layer located between the metal layer and the underlying intermediate RDL pad. The metal layer may have a different composition than the barrier layer, where the solder wettability of the metal layer may be greater than the solder wettability of the barrier layer. The relatively lower solder wettability of the barrier layer may constrain solder wetting along the sidewall of the bump structure. Such a configuration may help to minimize solder collapse and bridging defects during a bonding process used to bond the bump structures to a corresponding set of bonding structures on the second semiconductor device structure. In some embodiments, an additional barrier layer may be utilized in the bonding structures of the second semiconductor device structure to inhibit solder bridging from occurring on the second semiconductor device structure. In some embodiments, the metal layers of the bump structures and/or the intermediate RDL pad may include copper, and the barrier layer(s) may include nickel, iron, and/or tungsten.

In some embodiments, the bump structures and the intermediate RDL pads may be formed of different materials, where the material of the intermediate RDL pads may have less solder wettability than the material(s) of the bump structures. This may constrain solder wetting along the surface of the intermediate RDL pads and thereby minimize solder bridging defects between adjacent bump structures on the first semiconductor device structure.

In some embodiments, the widths of the second bonding structures on the second semiconductor device structure may be greater than the widths of the metal layers of the bump structures on the first semiconductor device structures. This may provide a relatively larger surface area on the second bonding structures to which the solder material may contact during the bonding process which may help to minimize solder wetting along the sidewalls of the bump structures and possible solder collapse.

In further embodiments, various characteristics of the intermediate RDL pads and the bump structures may be controlled to improve the flatness characteristics of the upper surface of the bump structures.

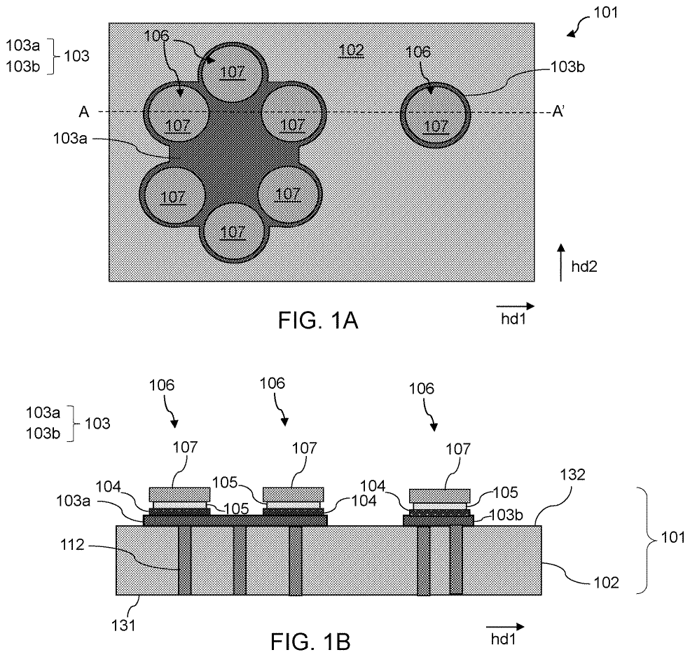

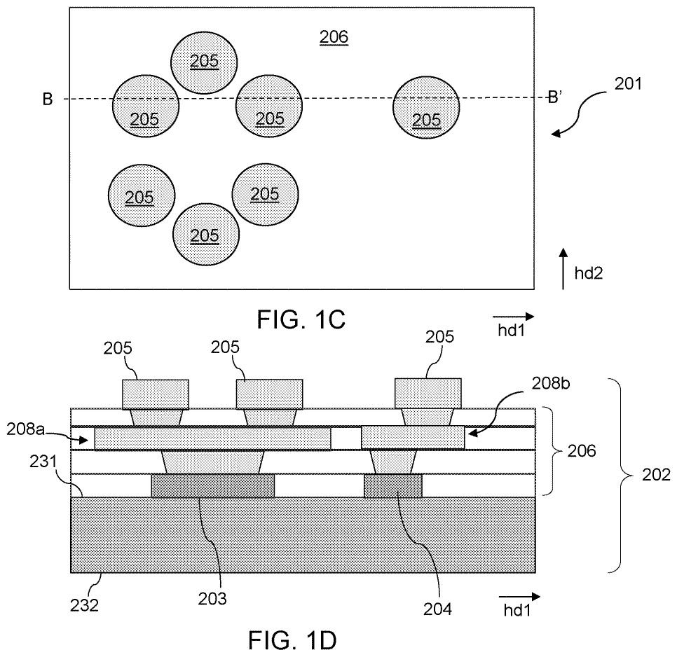

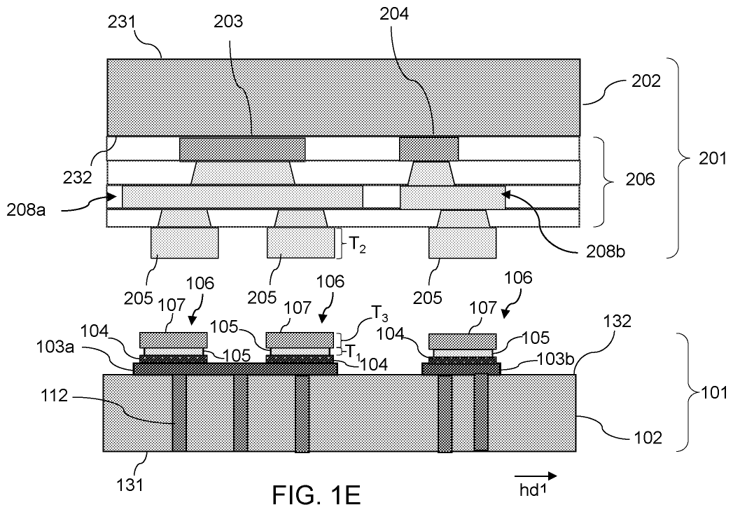

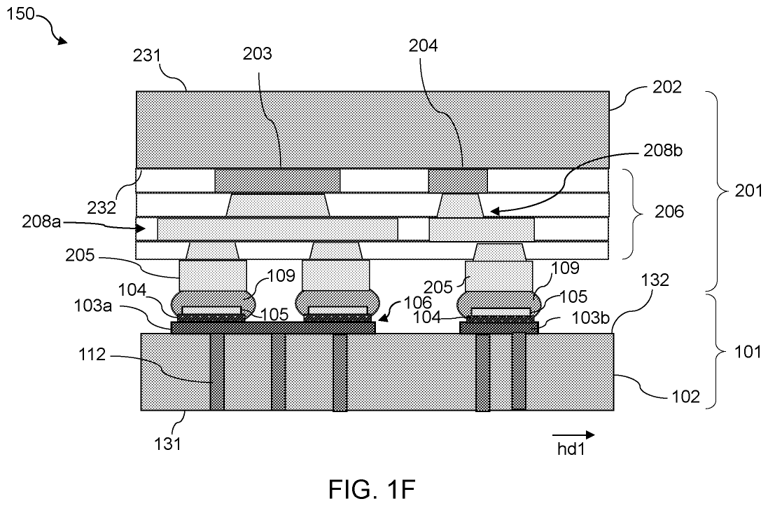

FIG. 1A is a top view of a first semiconductor device structure 101 according to various embodiments of the present disclosure. FIG. 1B is a vertical cross-sectional view of the semiconductor device structure 101 taken along line A-A′ in FIG. 1A. Referring to FIGS. 1A and 1B, the first semiconductor device structure 101 may include a first semiconductor substrate 102 that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 102 may be a semiconductor-on-insulator (SOI) substrate.

The first semiconductor substrate 102 may include a first major surface (i.e., a front side surface 131) and a second major surface (i.e., a backside surface 132). FIGS. 1A and 1B illustrate the first semiconductor device structure 101 in an inverted configuration such that the front side surface 131 of the first semiconductor substrate 102 is facing downward and the backside surface 132 of the first semiconductor substrate 102 faces upwards. In some embodiments, a plurality of devices (not shown in FIG. 1B) may be disposed on, over and/or in the front side surface 131 of the first semiconductor substrate 102. The devices may include, for example, active devices, passive devices, or a combination thereof. In some embodiments, the devices disposed on, over and/or in the front side surface 131 of the first semiconductor substrate 102 may include integrated circuit devices. The integrated circuit devices may include, for example, transistors (e.g., field-effect transistors (FETs)), capacitors, resistors, diodes, photodiodes, fuse devices, or other similar devices. In some embodiments, the integrated circuit devices may include gate electrodes, source/drain regions, spacers, isolation trenches, and the like.

The first semiconductor device structure 101 may additionally include an interconnect structure over the front side surface 131 of the first semiconductor substrate 102. The interconnect structure may include metal features (e.g., metal lines, vias, bonding pads, etc.) formed within a dielectric material (e.g., one or more inter-layer dielectric (ILD) layers and/or inter-metal dielectric (IMD) layers) that may provide connections to and/or between the various devices located on, over and/or in the front side surface 131 of the first semiconductor substrate 102.

In some embodiments, the first semiconductor device structure 101 may be a semiconductor die (i.e., a “chip”). For example, the first semiconductor device structure 101 may be a processor die, such as a system-on-chip (SoC), an application specific integrated circuit (ASIC) die, a central processing unit die, and/or a graphic processing unit die. In some embodiments, the first semiconductor device structure 101 may be a “chiplet” die configured to perform specific, limited processing functions. In some embodiments, the first semiconductor device structure 101 may be a memory die, such as a high bandwidth memory (HBM) die and/or a dynamic random access memory (DRAM) die.

Referring to FIG. 1B, the first semiconductor device structure 101 may include a plurality of through-substrate vias (TSVs) 112 extending through the first semiconductor substrate 102. The TSVs 112 may provide electrical connections between devices and/or interconnect structures on the front side surface 131 of the first semiconductor substrate 102 and the backside surface 132 of the first semiconductor substrate 102.

A plurality of first bonding structures may be formed over the backside surface 132 of the first semiconductor substrate 102. The first bonding structures may include a plurality of intermediate redistribution layer (RDL) pads 103 and a plurality of bump structures 106 located over the intermediate RDL pads 103. Each of the intermediate RDL pads 103 may overlie and may be electrically coupled to one or more of the TSVs 112 extending through the first semiconductor substrate 102. The plurality of intermediate RDL pads 103 may have non-uniform sizes and/or shapes. As shown in FIGS. 1A and 1B, for example, one or more first intermediate RDL pads 103a may have a size and/or shape that is different than the size and/or shape of one or more second intermediate RDL pads 103b. In some embodiments, a width dimension of the one or more first intermediate RDL pads 103a (i.e., a dimension within a plane containing the first horizontal direction hd1 and the second horizontal direction hd2 in FIG. 1A) may be greater than the corresponding width dimension of the one or more second intermediate RDL pads 103b. In some embodiments, a horizontal cross-section area of the one or more first intermediate RDL pads 103a may be greater than the horizontal cross-section area of the one or more second intermediate RDL pads 103b. In some embodiments, an array of intermediate RDL pads 103 may be formed over the backside surface 132 of the first semiconductor substrate 102, where a portion of the array of intermediate RDL pads 103 may include first intermediate RDL pads 103a, and a portion of the array of intermediate RDL pads 103 may include second intermediate RDL pads 103b. In some embodiments, the array may include additional intermediate RDL pads 103 (e.g., third intermediate RDL pads, fourth intermediate RDL pads, etc.) that may have different sizes and/or shapes than the first intermediate RDL pads 103a and the second intermediate RDL pads 103b.

Each of the intermediate RDL pads 103 (i.e., 103a, 103b collectively) may have substantially the same thickness in a vertical direction (i.e., in a direction perpendicular to horizontal directions hd1 and hd2). In particular, the average thicknesses of all the intermediate RDL pads 103 on the backside surface 132 of the first semiconductor substrate 102 may be within ±5% of one another. In one non-limiting embodiment, the thickness of each of the intermediate RDL pads 103 may be between about 1 μm and about 10 μm, such as between about 4 μm and about 6 μm (e.g., about 5 μm). Similarly, the width dimensions (i.e., the dimensions along hd1 and hd2) of each of the intermediate RDL pads 103 of each particular type of intermediate RDL pads 103 (i.e., first intermediate RDL pads 103a and second intermediate RDL pads 103b in FIGS. 1A and 1B) may have substantially the same dimensions, such that the width dimensions of each type of intermediate RDL pads 103 may be within ±5% of one another.

The intermediate RDL pads 103 may be formed of any suitable electrically conductive material, such as copper (Cu), tungsten (W), and aluminum (Al), including alloys and combinations thereof. Other electrically conductive materials are within the contemplated scope of disclosure.

Referring again to FIGS. 1A and 1B, bump structures 106 may be formed over each of the intermediate RDL pads 103. Each of the bump structures 106 may include a barrier layer 104 over the intermediate RDL pad 103 and a metal layer 105 over the barrier layer 104. The metal layer 105 may have a different composition than the barrier layer 104, where the solder wettability of the metal layer 105 may be greater than the solder wettability of the barrier layer 104 (e.g., as determined via a wetting balance analysis or similar recognized testing method). In various embodiments, the relatively lower solder wettability of the barrier layer 104 as compared to the metal layer 105 may constrain solder wetting along the sidewall of the bump structure 106, which may help to minimize solder collapse and bridging defects during a subsequent solder reflow process. A solder material layer 107 may optionally be formed over the metal layer 105 of the bump structures 106.

In various embodiments, the metal layer 105 of the bump structures 106 may be formed of a suitable metal material, such as copper (Cu), palladium (Pd), rhodium (Rh), gold (Au), and silver (Ag), including alloys and combinations thereof. In some embodiments, the intermediate RDL pads 103 and the metal layers 105 of the bump structures 106 may be composed of the same material (e.g., copper). Alternatively, the intermediate RDL pads 103 and the metal layers 105 may have different compositions. In some embodiments, the barrier layer 104 of the bump structures 106 may be formed of a suitable metal material such as nickel (Ni), iron (Fe), and tungsten (W), including alloys and combinations thereof. The solder material layer 107 may be composed of a suitable solder material, such as tin-silver (SnAg), tin-copper (SnCu), tin-gold-copper (SnAuCu), tin-lead (SnPb), or the like. Other suitable materials for the metal layer 105, the barrier layer 104, and the solder material layer 107 are within the contemplated scope of disclosure.

In various embodiments, each of the bump structures 106 formed on the first semiconductor device structure 101 may have the same critical dimensions (CDs). That is, dimensions of each of the bump structures 106, including the vertical height dimensions and/or the horizontal width dimensions of each of the bump structures 106, may be within ±5% of one another. In various embodiments, the thickness of each of the barrier layers 104 may be between about 0.5 μm and about 6 μm, such as between about 1 μm and about 3 μm (e.g., about 2 μm). The thickness of each of the metal layers 105 may be between about 1 μm and about 8 μm, such as between about 2 μm and about 4 μm (e.g., about 3 μm). In some embodiments, a thickness of the metal layers 105 may be greater than a thickness of the barrier layers 104. In some embodiments, a thickness of the intermediate RDL pads 103 may be greater than a thickness of the metal layers 105. In some embodiments, the thickness of the solder material layer 107 may be between about 1 μm and about 10 μm, such as between about 5 μm and about 7 μm (e.g., about 6 μm). In some embodiments, a thickness of the solder material layers 107 may be greater than the thicknesses of the intermediate RDL pads 103, the barrier layers 104, and the metal layers 105.

In some embodiments, the width dimensions (i.e., within a horizontal plane containing hd1 and hd2) of the metal layers 105 may be between about 10 μm and about 20 μm, such as between about 14 μm and about 18 μm (e.g., about 16 μm). In some embodiments, the width dimensions of barrier layers 104 may be larger than the width dimensions of the metal layers 105, as shown in FIG. 1B. In some embodiments, the width dimensions of the solder material layers 107 may be larger than the width dimensions of the metal layers 105.

In various embodiments, the intermediate RDL pads 103, the barrier layers 104, the metal layers 105, and the solder material layers 107 may be formed using suitable deposition process(es), such as, for example, physical vapor deposition (PVD), sputtering, chemical vapor deposition (CVD), atomic layer deposition (ALD), plasma-enhanced chemical vapor deposition (PECVD), electrochemical deposition (e.g., plating), or combinations thereof. In some embodiments, the intermediate RDL pads 103, the barrier layers 104, the metal layers 105, and/or the solder material layer 107 may be formed via an electrochemical deposition process. For example, a first mask layer may be formed over the backside surface 132 of the first semiconductor substrate 102 and may be patterned using photolithographic techniques to remove portions of the first mask layer and form a patterned mask. Openings formed through the mask may correspond to the size, shape, and locations of the intermediate RDL pads 103 to be subsequently formed. Then, an electrodeposition process (e.g., electroplating, electroless deposition, etc.) may be used to deposit a metal material (e.g., Cu) within the openings through the mask to form the intermediate RDL pads 103. Following the deposition of the intermediate RDL pads 103, the mask may optionally be removed. This process of forming and patterning a mask, and depositing material within openings through the mask, may be repeated one or more additional times in order to form the barrier layers 104 over the intermediate RDL pads 103, the metal layers 105 over the barrier layers 104, and/or the solder material layers 107 over the metal layers.

FIG. 1C is a top view of a second semiconductor device structure 201 according to various embodiments of the present disclosure. FIG. 1D is a vertical cross-section view of the second semiconductor device structure 201 taken along line B-B′ in FIG. 1C. Referring to FIGS. 1C and 1D, the second semiconductor device structure 201 may include a second semiconductor substrate 202. The second semiconductor substrate 202 may include a suitable semiconductor material as described above with reference to the first semiconductor substrate 102. In some embodiments, the second semiconductor substrate 202 may be composed of the same material as the first semiconductor substrate 102. Alternatively, the second semiconductor substrate 202 and the first semiconductor substrate 102 may be composed of different materials. The second semiconductor substrate 202 may include a second major surface (i.e., a front side surface 231) and a third major surface (i.e., a backside surface 232). In some embodiments, a plurality of devices (not shown in FIG. 1D) may be located on, over and/or in the front side surface 231 of the second semiconductor substrate 202. The devices may include, for example, active devices, passive devices, or a combination thereof. In some embodiments, the devices located on, over and/or in the front side surface 231 of the second semiconductor substrate 202 may include integrated circuit devices. The integrated circuit devices may include, for example, transistors (e.g., field-effect transistors (FETs)), capacitors, resistors, diodes, photodiodes, fuse devices, or other similar devices. In some embodiments, the integrated circuit devices may include gate electrodes, source/drain regions, spacers, isolation trenches, and the like.

The second semiconductor device structure 201 may additionally include an interconnect structure over the front side surface 231 of the second semiconductor substrate 202. The interconnect structure may include metal features (e.g., metal lines and vias) embedded within a dielectric material (e.g., one or more inter-layer dielectric (ILD) layers and/or inter-metal dielectric (IMD) layers) that may provide connections to and/or between the various devices located on, over and/or in the front side surface 231 of the second semiconductor substrate 202.

In some embodiments, the second semiconductor device structure 201 may be a semiconductor die (i.e., a “chip”). For example, the second semiconductor device structure 201 may be a processor die, such as a system-on-chip (SoC), an application-specific integrated circuit (ASIC) die, a central processing unit die, and/or a graphic processing unit die. In some embodiments, the second semiconductor device structure 201 may be a “chiplet” die configured to perform specific, limited processing functions. In some embodiments, the second semiconductor device structure 201 may be a memory die, such as a high bandwidth memory (HBM) die and/or a dynamic random-access memory (DRAM) die. The first semiconductor device structure 101 and the second semiconductor device structure 201 may be the same type of die (e.g., processor dies, memory dies, etc.) or they may be different types of dies. In one non-limiting embodiment, the first semiconductor device structure 101 may be a chiplet, and the second semiconductor device structure 201 may be a processor die, such as a SoC die.

Referring again to FIGS. 1C and 1D, an upper portion of an interconnect structure formed over the front side surface 231 of the second semiconductor substrate 202 is shown, including a plurality of dielectric material layers 206, metal features (203, 204, 208a and 208b) located within the dielectric material layers 206, and an array of second bonding structures 205 located over the dielectric material layers 206. It will be understood that the interconnect structure may include additional structures, including additional dielectric layers and metal features located between the upper portion of the interconnect structure shown in FIGS. 1C and 1D and the front side surface 231 of the second semiconductor substrate 202. Referring again to FIGS. 1C and 1D, the metal features (203, 204, 208a and 208b) and second bonding structures 205 may be used to transmit different types of electronic signals to and/or from the second semiconductor device structure 201. For example, a first subset of the metal features and second bonding structures 205 may be used to transmit electric power to and/or from the second semiconductor device structure 201, and a second subset of the metal features and second bonding structures 205 may be used to transmit data signals (e.g., die-to-die (D2D) communication signals) to and/or from the second semiconductor device structure 201. The different types of electronic signals may have different requirements in terms of the current-and/or voltage-carrying capacities of the interconnect structures used to transmit the signals. For example, as shown in FIG. 1D, a first via 203 may be used to carry electrical power to and/or from the second semiconductor device structure 201, and a second via 204 may be used to carry data signals to and/or from the second semiconductor device structure 201. The first via 203 may have a larger diameter than the second via 204 to accommodate the different current and/or voltage characteristics of the power signals as compared to the data signals.

In various embodiments, it may be advantageous to form the second bonding structures 205 with common critical dimensions (CD) and optionally having the same spacing (pitch) between adjacent second bonding structures 205. For example, as described above, forming bonding structures having different CDs and/or pitches for the different types of signals transmitted to and/or from the second semiconductor device structure 201 may result in poor co-planarity characteristics and/or added costs. Accordingly, in various embodiments, an array of second bonding structures 205 having uniform sizes and optionally a uniform pitch may be formed. A first set of metal features 208a (e.g., metal lines and/or vias) may be used to connect the first via 203 to a first set of one or more second bonding structures 205, and a second set of metal features 208b (e.g., metal lines and/or vias) may be used to connect the second via 204 to a second set of one or more second bonding structures 205. In the embodiment shown in FIGS. 1C and 1D, each first via 203 may be electrically coupled to multiple second bonding structures 205 via the first set of metal features 208a, and each second via 204 may be electrically coupled to a single second bonding structure 205 by the second set of metal features 208b. Thus, signals of a first type (e.g., power signals) may be transmitted to or from the second semiconductor device structure 201 over a plurality of second bonding structures 205 connected in parallel, while signals of a second type (e.g., data signals) may be transmitted to or from the second semiconductor device structure 201 over a single bonding structure 205.

Referring again to FIGS. 1C and 1D, the dielectric material layers 206 may be formed of suitable dielectric materials such as silicon oxide, silicon nitride, silicon carbide, or the like. Other dielectric materials are within the contemplated scope of disclosure. The dielectric material layers 206 may be deposited using a suitable deposition process, such as a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like. The metal features (203, 204, 208a and 208b) may be formed within the dielectric material layers 206, such as via a damascene or dual-damascene process. The metal features (203, 204, 208a and 208b) may include a suitable conductive material, such as copper (Cu), tungsten (W), aluminum (Al), and the like. The metal features (203, 204, 208a and 208b) may be formed using a suitable deposition process, such as, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

The second bonding structures 205 may be formed over the dielectric material layers 206, and may be electrically coupled to the metal features (203, 204, 208a and 208b) located within the dielectric material layers 206. The second bonding structures 205 may be formed of a suitable metal material, such as copper (Cu), palladium (Pd), rhodium (Rh), gold (Au), and silver (Ag), including alloys and combinations thereof. In some embodiments, the second bonding structures 205 may be formed of the same material as the metal layers 105 of the bump structures 106 on the first semiconductor device structure 101. The second bonding structures 205 may be formed using a suitable deposition process, as described above. In some embodiments, the second bonding structures 205 may be formed via an electrochemical deposition process (e.g., plating process), as described above. Thus, each of the second bonding structures 205 may include at least one metal portion. In the embodiment shown in FIGS. 1C and 1D, the entirety of the second bonding structure 205 may include a metal portion.

In various embodiments, each of the second bonding structures 205 may have the same critical dimensions (CD). In some embodiments, the width dimensions of the second bonding structures 205 may be equal to or substantially equal to the width dimensions of the metal layers 105 of the bump structures 106 on the first semiconductor device structure 101. Alternatively, the width dimensions of the second bonding structures 205 may differ from the width dimension of the metal layers 105 of the bump structures 106, as described in further detail below. The second bonding structures 205 on the second semiconductor device structure 201 may form an array of second bonding structures 205 having a pattern and layout that corresponds to the pattern and layout of the bump structures 106 on the first semiconductor device structure 101.

FIG. 1E is a vertical cross-sectional view illustrating the second semiconductor device structure 201 aligned over the first semiconductor device structure 101 according to various embodiments of the present disclosure. Referring to FIG. 1E, the second semiconductor device structure 201 may be inverted (i.e., flipped over) relative to its orientation as shown in FIGS. 1C and 1D such that the front side surface 231 of the second semiconductor substrate 202 faces downwards and the backside surface 232 of the second semiconductor substrate 102 faces upwards. The second semiconductor device structure 201 may be aligned over the first semiconductor device structure 101 such that each of the second bonding structures 205 of the second semiconductor device structure 201 may be aligned with a corresponding bump structure 106 of the first semiconductor device structure 101. Although FIG. 1E illustrates the second semiconductor device structure 201 aligned over the first semiconductor device structure 101, it will be understood that in other embodiments, the first semiconductor device structure 101 may be aligned over the second semiconductor device structure 201.

Referring again to FIG. 1E, the metal layers 105 of the bump structures 106 may have a thickness, T₁, the second bonding structures 205 may have a thickness, T₂, and the solder material layer 107 may have a thickness, T₃. In various embodiments, the thickness, T₂, of the second bonding structures 205 may be between about 3 μm and about 15 μm, such as between about 5 μm and about 10 μm (e.g., about 8 μm). In some embodiments, a thickness of the metal layers 105 may be greater than a thickness of the barrier layers 104. In some embodiments, the thickness, T₂, of the second bonding structures 205 may be greater than the thicknesses of the intermediate RDL pads 103, the barrier layers 104, and the metal layers 105, and the solder material layers 107. In some embodiments, 2×(T₁+T₂)≥T₃. That is, the combined thickness of the metal layers 105 and the second bonding structures 205 may be equal to or greater than half the thickness of the solder material layers 107. This may help to promote adequate intermetallic compound (IMC) formation during a subsequent solder reflow process used to bond the first semiconductor device structure 101 to the second semiconductor device structure 201 and may also help to reduce or eliminate solder bridging defects (e.g., when there is too much solder material) and/or solder necking defects (e.g., when there not enough solder material).

FIG. 1F is a vertical cross-sectional view of a vertically stacked semiconductor device 150 according to various embodiments of the present disclosure. Referring to FIG. 1F, the second semiconductor device structure 201 may be brought into contact with the first semiconductor device structure 101 such that a solder material layer 107 may be located between and may contact a metal layer 105 of a bump structure 106 of the first semiconductor device structure 101 and a corresponding second bonding structure 205 of the second semiconductor device structure 201. A reflow process may then be performed that includes subjecting the assembly including first semiconductor device structure 101 and the second semiconductor device structure 201 to an elevated temperature that is above the melting point of the solder material layers 107. This may cause at least a portion of the solder material layers 107 to melt and form a liquid phase. The molten solder material may create a metallurgical bond between the metal layers 105 of the bump structures 106 on the first semiconductor device structure 101 and the second bonding structures 205 on the second semiconductor device structure 201. The assembly may then be cooled, causing the solder material to solidify and form solder joints 109 that physically and electrically couple each of the metal layers 105 of the bump structures 106 on the first semiconductor device structure 101 to a corresponding second bonding structure 205 on the second semiconductor device structure 201.

In some embodiments, the reflow process may induce the formation of intermetallic compound (IMC) layers. The IMC layers may be formed at the interfaces between the molten solder material and the metal layers 105 of the bump structures 106, as well as at the interfaces between the molten solder material and the second bonding structures 205. IMC layers may optionally form at interfaces between the molten solder material and the barrier layers 104, and in some cases, at interfaces between the molten solder material and the intermediate RDL pads 103. In some embodiments, the IMC layers may include tin and one or more of copper, nickel, iron, and tungsten.

As discussed above, the relatively lower solder wettability of the barrier layers 104 of the bump structures 106 may inhibit solder wetting along the sidewalls of the bump structures 106. Accordingly, solder wetting of the underlying intermediate RDL pads 103 may be reduced or eliminated, which may reduce the incidence of solder bridging between multiple bump structures 106.

Referring again to FIG. 1F, the vertically stacked semiconductor device 150 includes a first semiconductor device structure 101 bonded to a second semiconductor device structure 201 via a plurality of solder joints 109. Signals of a first type (e.g., power signals) may be transmitted between the first semiconductor device structure 101 and the second semiconductor device structure 201 over a first signal path that includes a first via 203, a first set of metal features 208a, a plurality of second bonding structures 205, a plurality of solder joints 109, a plurality of bump structures 106, and a first intermediate RDL pad 103a. The first signal path may also include at least one TSV 112 through the first semiconductor substrate 102 of the first semiconductor device structure 101 that underlies the first intermediate RDL pad 103a. Signals of a second type (e.g., data signals) may be transmitted between the first semiconductor device structure 101 and the second semiconductor device structure 201 over a second signal path that includes a second via 204, a second set of metal features 208b, a single second bonding structure 205, a single solder joint 109, a single bump structure 106, and a second intermediate RDL pad 103b. The second signal path may also include at least one TSV 112 through the first semiconductor substrate 102 of the first semiconductor device structure 101 that underlies the second intermediate RDL pad 103b.

The vertically stacked semiconductor device 150 shown in FIG. 1F includes the first semiconductor device structure 101 bonded to the second semiconductor device structure 201 such that the front side surface 231 of the second semiconductor substrate 202 and the backside surface 132 of the first semiconductor substrate 102 face toward each other. Thus, the vertically stacked semiconductor device 150 may have a front-to-back configuration. However, it will be understood that other embodiments of the vertically stacked semiconductor device 150 may have a different configuration, such as a front-to-front configuration or a back-to-back configuration.

Further, although FIGS. 1E and 1F illustrate a bonding process whereby the second semiconductor device structure 201 is aligned over and bonded to the first semiconductor device structure 101 (i.e., the second semiconductor device 201 is the “top” structure and the first semiconductor device structure 101 is the “bottom” structure in the vertically stacked semiconductor device 150), it will be understood that following the bonding process, the orientation of the vertically stacked semiconductor device 150 may be inverted such that the first semiconductor device structure 101 may be the “top” structure and the second semiconductor device structure 201 may be the “bottom” structure in the vertically stacked semiconductor device 150.

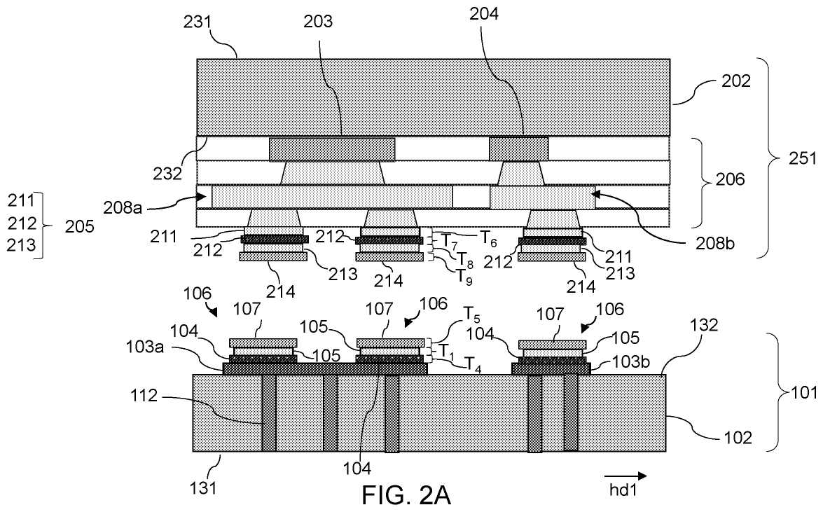

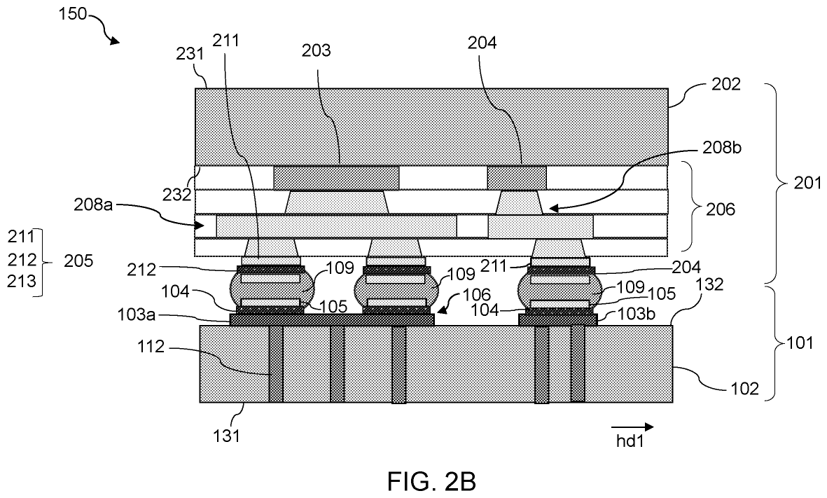

FIG. 2A is a vertical cross-sectional view illustrating a second semiconductor device structure 201 aligned over a first semiconductor device structure 101 according to another embodiment of the present disclosure. The first semiconductor device structure 101 and the second semiconductor device structure 201 shown in FIG. 2A may be similar to the first semiconductor device structure 101 and the second semiconductor device structure 201 described above with reference to FIGS. 1A-1F. Thus, repeated discussion of like elements is omitted for brevity. The embodiment shown in FIG. 2A differs from the embodiment shown in FIG. 1A-1F in that each of the second bonding structures 205 of the second semiconductor device structure 201 includes a multi-layer structure that may comprise a first metal portion 211, a barrier layer 212, and a second metal portion 213. Each of the first metal portions 211 may be formed over the dielectric material layers 206 and may be electrically coupled to the metal features (203, 204, 208a and 208b) located within the dielectric material layers 206. The barrier layers 212 may be formed over the first metal portions 211. The second metal portions 213 may be formed over the barrier layers 212. A solder material layer 214 may optionally be formed over the second metal portion 213. The second semiconductor device structure 201 may then be inverted (i.e., flipped over) and aligned over the first semiconductor device structure 101 as shown in FIG. 2A.

In various embodiments, the barrier layers 212 may have a different composition than the first metal portions 211 and the second metal portions 213. The barrier layers 212 may have a lower solder wettability than the first metal portions 211 and the second metal portions 213. In various embodiments, the first metal portions 211 and the second metal portions 213 may be formed of a suitable metal material, such as copper (Cu), palladium (Pd), rhodium (Rh), gold (Au), and silver (Ag), including alloys and combinations thereof. In some embodiments, the first metal portions 211, the second metal portions 213 and the metal layers 105 of the bump structures 106 may all be composed of the same material(s). Alternatively, the first metal portions 211, the second metal portions 213 and/or the metal layers 105 may have different compositions. In some embodiments, the barrier layers 212 may be formed of a suitable metal material such as nickel (Ni), iron (Fe), and tungsten (W), including alloys and combinations thereof. The solder material layers 214 may be composed of a suitable solder material, such as tin-silver (SnAg), tin-copper (SnCu), tin-gold-copper (SnAuCu), tin-lead (SnPb), or the like. In some embodiments, the solder material layers 214 may have the same composition as the solder material layers 107 located over the metal layers 105 of the bump structures 106. Alternatively, the solder material layers 214 and the solder material layers 107 may have different compositions.

In various embodiments, the thickness, T₆, of the first metal portions 211 may be between about 1 μm and about 8 μm, such as between about 2 μm and about 4 μm (e.g., about 3 μm). The thickness, T₇, of the barrier layers 212 may be between about 0.5 μm and about 6 μm, such as between about 1 μm and about 3 μm (e.g., about 2 μm). The thickness, T₈, of the second metal portions 213 may be between about 1 μm and about 8 μm, such as between about 2 μm and about 4 μm (e.g., about 3 μm). In some embodiments, the thickness, T₉, of the solder material layers 214 may be between about 0.5 μm and about 7 μm, such as between about 2 μm and about 4 μm (e.g., about 3 μm).

The embodiment shown in FIG. 2A may also differ from the embodiment shown in FIGS. 1A-1F in that the thickness, T₅, of the solder material layers 107 over the metal layers 105 of the bump structures 106 on the first semiconductor device structure 101 may be less than the thickness of the solder material layer 107 in the embodiment of FIGS. 1A-1E. In some embodiments, the thickness, T₄, of the barrier layers 104 over the metal layers 105 of the bump structures 106 may be at least as great as the thickness, T₇, of the barrier layers 212 over the second metal portions 213 of the second bonding structures 205 (i.e., T₄≥T₇). In some embodiments, twice the combined thicknesses of the first metal portions 211 and the second metal portions 213 may be at least as great as the combined thicknesses of the solder material layers 107 and 214 (i.e., 2 ×(T₆+T₈)≥(T₅+T₉)).

In some embodiments, the width dimensions of barrier layers 212 may be larger than the width dimensions of the first and second metal portions 211 and 213, as shown in FIG. 2A. In some embodiments, the width dimensions of the solder material layers 214 may be larger than the width dimensions of the first and second metal portions 211 and 213.

FIG. 2B is a vertical cross-sectional view of a vertically stacked semiconductor device 150 according to another embodiment of the present disclosure. Referring to FIG. 2B, the second semiconductor device structure 201 may be brought into contact with the first semiconductor device structure 101 such that the solder material layer 107 on the first semiconductor device structure 101 contacts the solder material layer 214 on the second semiconductor device structure 201. A reflow process may be performed as described above with reference to FIG. 1F to form solder joints 109 extending between each of the bump structures 106 on the first semiconductor device structure 101 and a corresponding second bonding structure 205 on the second semiconductor device structure 201. The relatively lower degree of solder wettability of the barrier layers 104, 212 in the bump structures 106 of the first semiconductor device structure 101 and in the second bonding structures 205 of the second semiconductor device structure 201 may help to constrain sidewall solder wetting on both the bump structures 106 and the second bonding structures 205. This may help to inhibit solder bridging defects from occurring on both the first semiconductor device structure 101 and on the second semiconductor device structure 201, which may provide improved yield for the vertically stacked semiconductor device 150.

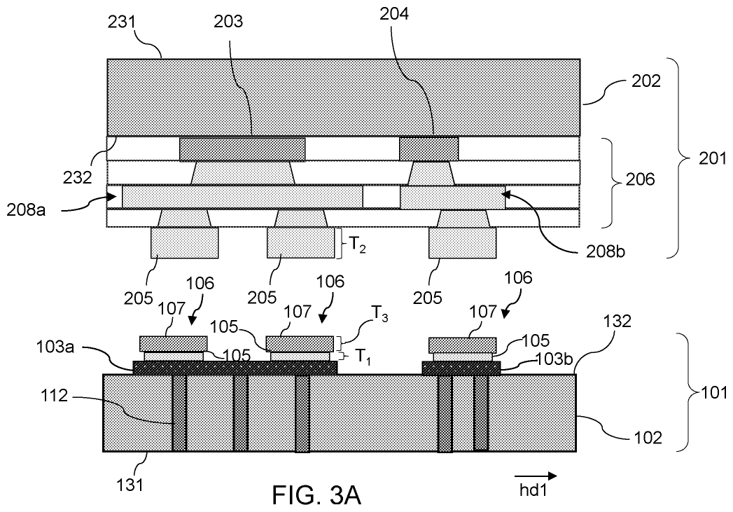

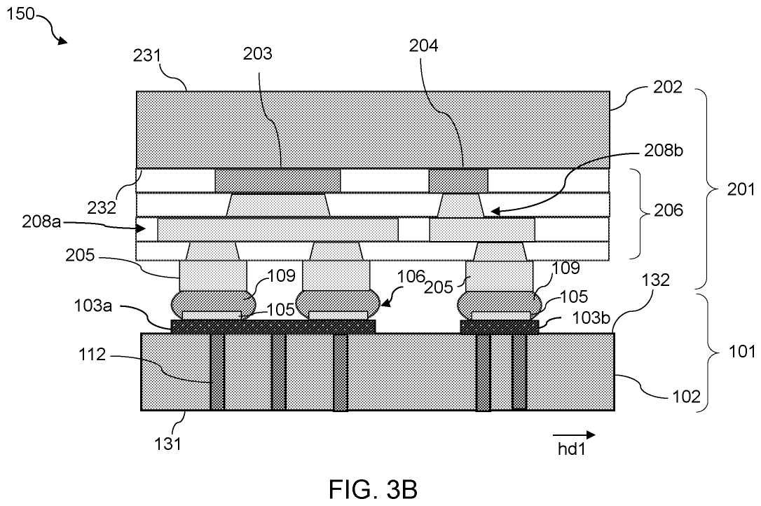

FIG. 3A is a vertical cross-sectional view illustrating a second semiconductor device structure 201 aligned over a first semiconductor device structure 101 according to another embodiment of the present disclosure. The first semiconductor device structure 101 and the second semiconductor device structure 201 shown in FIG. 3A may be similar to the first semiconductor device structure 101 and the second semiconductor device structure 201 described above with reference to FIGS. 1A-1F. Thus, repeated discussion of like elements is omitted for brevity. The embodiment shown in FIG. 3A differs from the embodiment shown in FIG. 1A-1F in that the barrier layers 104 are omitted from the bump structures 106 of the first semiconductor device structure 101. Thus, each bump structure 106 includes an above-described metal layer 105 over an intermediate RDL pad 103. An above-described solder material layer 107 may optionally be located over the metal layer 105. In addition, the first intermediate RDL pads 103a and the second intermediate RDL pads 103b may be composed of a material having a lower solder wettability than the material of the metal layers 105. In some embodiments, the first intermediate RDL pads 103a and the second intermediate RDL pads 103b may be formed of a suitable metal material such as nickel (Ni), iron (Fe), and tungsten (W), including alloys and combinations thereof. The metal layers 105 may be formed of a suitable metal material, such as copper (Cu), palladium (Pd), rhodium (Rh), gold (Au), and silver (Ag), including alloys and combinations thereof.

In the embodiment of FIG. 3A, the relatively lower solder wettability of the intermediate RDL pads 103 may help to inhibit solder bridging defects occurring between adjacent bump structures 106 during the subsequent bonding process. The embodiment shown in FIG. 3A may also differ from the embodiment shown in FIGS. 1A-1F in that the thickness of the intermediate RDL pads 103 in the embodiment of FIG. 3A may be greater than the thickness of the intermediate RDL pads 103 in the embodiment of FIGS. 1A-1F. In one non-limiting embodiment, the thickness of each of the intermediate RDL pads 103 in the embodiment of FIG. 3A may be between about 2 μm and about 15 μm, such as between about 5 μm and about 9 μm (e.g., about 7 μm). The relatively greater thickness of the intermediate RDL pads 103 may compensate for the lack of a barrier layer in the bump structures 106, such that a desired vertical gap between the backside surface 132 of the first semiconductor substrate 102 and the solder joint to be subsequently formed may be maintained.

FIG. 3B is a vertical cross-sectional view of a vertically stacked semiconductor device 150 according to another embodiment of the present disclosure. Referring to FIG. 3B, the second semiconductor device structure 201 may be brought into contact with the first semiconductor device structure 101 such that the solder material layers 107 on the first semiconductor device structure 101 contact the second bonding structures 205 on the second semiconductor device structure 201. A reflow process may be performed as described above with reference to FIG. 1F to form solder joints 109 extending between each of the bump structures 106 on the first semiconductor device structure 101 and a corresponding second bonding structure 205 on the second semiconductor device structure 201. Although in the embodiment shown in FIGS. 3A and 3B illustrates the second bonding structures 205 as including a single metal layer, it will be understood that the second bonding structures 205 on the second semiconductor device structure 201 may include a multi-layer structure as described above with reference to FIGS. 2A and 2B.

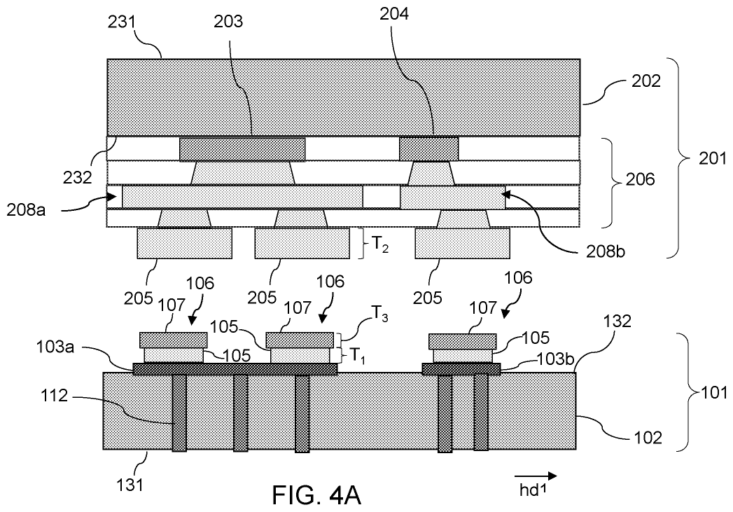

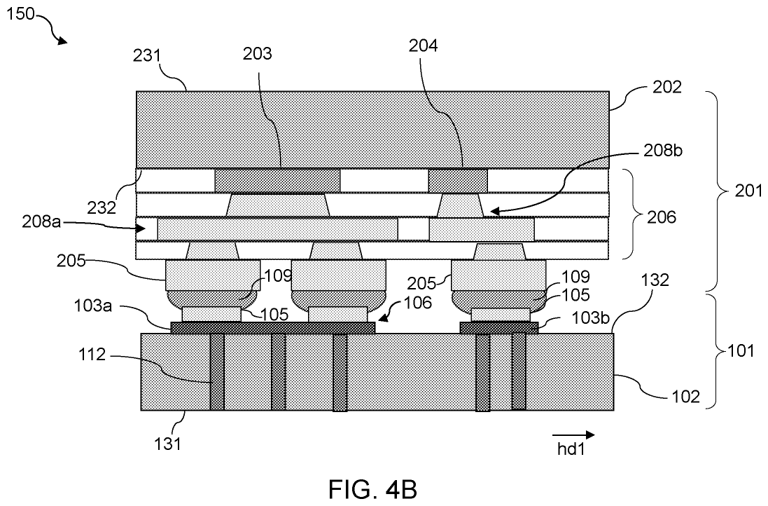

FIG. 4A is a vertical cross-sectional view illustrating a second semiconductor device structure 201 aligned over a first semiconductor device structure 101 according to another embodiment of the present disclosure. The first semiconductor device structure 101 and the second semiconductor device structure 201 shown in FIG. 4A may be similar to the first semiconductor device structure 101 and the second semiconductor device structure 201 described above with reference to FIGS. 1A-1F. Thus, repeated discussion of like elements is omitted for brevity. The embodiment shown in FIG. 4A differs from the embodiment shown in FIG. 1A-1F in that each of the second bonding structures 205 of the second semiconductor device structure 201 has a larger width dimension than the width dimensions of the metal layers 105 of the bump structures 106 of the first semiconductor device structure 101. In various embodiments, the width dimensions of the second bonding structures 205 may be at least 10%, such as at least 12% greater than the width dimensions of the metal layers 105. In some embodiments, the width dimensions of the second bonding structures 205 may be at least 2 μm greater than the width dimensions of the metal layers 105.

In various embodiments, the relatively greater width dimensions of the second bonding structures 205 may provide a larger surface area for the solder material to contact during the subsequent bonding process. This may promote a greater amount of IMC formation on the second bonding structures 205 of the second semiconductor device structure 201, which may help to minimize solder collapse along the sidewalls of the bump structures 106 and over the intermediate RDL pads 103, thereby avoiding solder bridge defects.

The embodiment shown in FIG. 4A also differs from the embodiment shown in FIG. 1A-1F in that the barrier layers 104 are omitted from the bump structures 106 of the first semiconductor device structure 101. Thus, each bump structure 106 includes an above-described metal layer 105 over an intermediate RDL pad 103. An above-described solder material layer 107 may optionally be located over the metal layer 105. The embodiment shown in FIG. 4A may also differ from the embodiment shown in FIGS. 1A-1F in that the thickness, T₁, of the metal layer 105 in the embodiment of FIG. 4A may be greater than the thickness of the metal layers 105 in the embodiment of FIGS. 1A-1F. In one non-limiting embodiment, the thickness of each of the metal layers 105 in the embodiment of FIG. 4A may be between about 1 μm and about 10 μm, such as between about 4 μm and about 6 μm (e.g., about 5 μm). The relatively greater thickness of the metal layers 105 may compensate for the lack of a barrier layer in the bump structures 106, such that a desired vertical gap between the backside surface 132 of the first semiconductor substrate 102 and the solder joint to be subsequently formed may be maintained.

FIG. 4B is a vertical cross-sectional view of a vertically stacked semiconductor device 150 according to another embodiment of the present disclosure. Referring to FIG. 4B, the second semiconductor device structure 201 may be brought into contact with the first semiconductor device structure 101 such that the solder material layers 107 on the first semiconductor device structure 101 contact the second bonding structures 205 on the second semiconductor device structure 201. A reflow process may be performed as described above with reference to FIG. 1F to form solder joints 109 extending between each of the bump structures 106 on the first semiconductor device structure 101 and a corresponding second bonding structure 205 on the second semiconductor device structure 201. Although in the embodiment shown in FIGS. 4A and 4B illustrates the second bonding structures 205 as including a single metal layer, it will be understood that the second bonding structures 205 on the second semiconductor device structure 201 may include a multi-layer structure as described above with reference to FIGS. 2A and 2B, where the multi-layer second bonding structures 205 may include larger width dimensions than the metal layers 105 of the bump structures 106 of the first semiconductor device structure 101. Alternatively, or in addition, the bump structures 106 of the first semiconductor device structure 101 may include an above-described barrier layer 104, as described above with reference to FIGS. 1A-1F, and/or the intermediate RDL pads 103 may be composed of a material having relatively lower solder wettability compared to the material of the metal layers 105, as is described above with reference to FIGS. 3A and 3B.

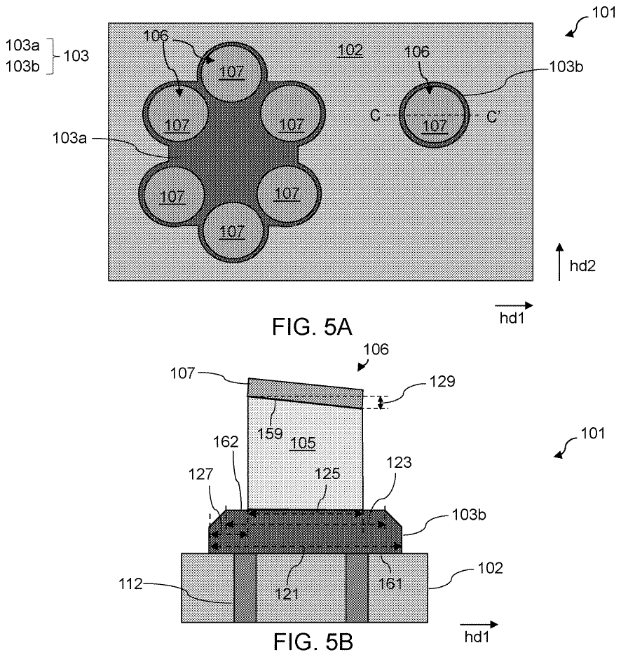

Further embodiments include bonding structures having a bump structure over an intermediate RDL pad with improved coplanarity characteristics and methods therefor. FIG. 5A is a top view of a first semiconductor device structure 101 according to various embodiments of the present disclosure. FIG. 5B is a vertical cross-section view of the first semiconductor device structure 101 taken along line C-C′ in FIG. 5A. The first semiconductor device structure 101 shown in FIGS. 5A and 5B may be similar to the first semiconductor device structure 101 described above with reference to FIGS. 1A-1F. Thus, repeated discussion of like elements is omitted for clarity. The first semiconductor device structure 101 shown in FIGS. 5A and 5B may differ from the embodiment shown in FIG. 1A-1F in that the bump structures 106 include an above-described metal layer 105 over an intermediate RDL pad 103 and a solder material layer 107 over the metal layer 105, and the above-described barrier layers 104 may be omitted. However, it will be understood that in other embodiments, the bump structures 106 may also include barrier layers 104.

FIG. 5B is a vertical cross-section view that depicts a portion of the first semiconductor device structure 101 including a second intermediate RDL pad 103b, and a bump structure 106 including a metal layer 105 over the second intermediate RDL pad 103b. A solder material layer 107 is located over the upper surface 159 of the metal layer 105. An important consideration in improving the bonding characteristics and yields of a vertically-stacked semiconductor device as described above is the degree of coplanarity of the bump structures 106, and in particular, the coplanarity characteristics of the upper surface 159 of the metal layer 105 that contacts the solder material layer 107. The maximum variation in vertical elevation around the periphery of the upper surface 159 of the metal layer 105 may be referred to as the “flatness delta” 129 of the bump structure 106, as illustrated in FIG. 5B. The flatness delta 129 may be used to quantify the degree of “tilt” of the upper surface 159 of the metal layer 105 relative to a horizontal reference plane. An excessive amount of tilt (i.e., a high flatness delta 129) may result in poor bond formation, solder collapse, and other defects that may negatively affect device yields. In some embodiments, the flatness delta 129 of the bump structures 106 may be ≤0.8 μm to provide effective bonding.

However, it may be difficult to maintain flatness deltas of 0.8 μm or less in a bump structure 106 as shown in FIGS. 5A and 5B. This may be in part due to variations in the thickness of the intermediate RDL pad 103 on which the bump structure 106 is formed. As shown in the cross-section view of FIG. 5B, the intermediate RDL pad 103 (which in this example is a second intermediate RDL pad 103b) includes a lower surface 161 and a flat upper surface 162. The lower surface 161 of the intermediate RDL pad 103 has a width dimension 121 that is greater than a width dimension 123 of the flat upper surface 162 of the intermediate RDL pad 103. Thus, portions of the sidewalls of the intermediate RDL pad 103 extending between the lower surface 161 and the flat upper surface 162 may taper inwardly between the lower surface 161 and the flat upper surface 162 as shown in FIG. 5B. The shape of the intermediate RDL pads 103 including a relatively wider lower surface 161 and narrower flat upper surface 162 may be at least partially the result of the deposition process (e.g., electroplating) and process conditions used to form the intermediate RDL pad 103.

Referring again to FIG. 5B, the width dimension 125 of the metal layer 105 of the bump structure 106 may be less than the width dimension 121 of the lower surface 161 of the intermediate RDL pad 103. The peripheral edges of the metal layer 105 may be offset from the peripheral edges of the intermediate RDL pad 103 by a target enclosure distance 127. In some embodiments, the target enclosure distance 127 may be ≥2.5 μm. To provide a high degree of coplanarity and minimize the flatness delta 129 of the bump structures 106, the metal layer 105 may be located on the flat upper surface 162 of the intermediate RDL pad 103 rather than on the tapered portions of the intermediate RDL pads 103. Thus, providing a relatively larger width dimension 121 of the flat upper surface 162 relative to the overall width dimension 123 of the intermediate RDL pad 103 may help to increase coplanarity and minimize the flatness delta 129. In some embodiments, the width dimension 121 of the flat upper surface 162 may be at least as great as the width dimension 125 of the metal layer 105. In some embodiments, the width dimension 121 of the flat upper surface 162 may be at least 2% greater, including at least 5% greater, such as at least 6% greater, than the width dimension 125 of the metal layer 105. In some embodiments, the width dimension 121 of the flat upper surface 162 may be controlled, in part, by controlling a deposition rate of the intermediate RDL pad 103. In one non-limiting example, the intermediate RDL pad 103 may be formed by electro-plating with a deposition rate of at least about 3 amperes per decimeter squared (A/dm²) (e.g., between about 3 and about 5 A/dm²), such as at least about 4 A/dm², to provide a relatively wider flat upper surface 162 of the intermediate RDL pad 103.

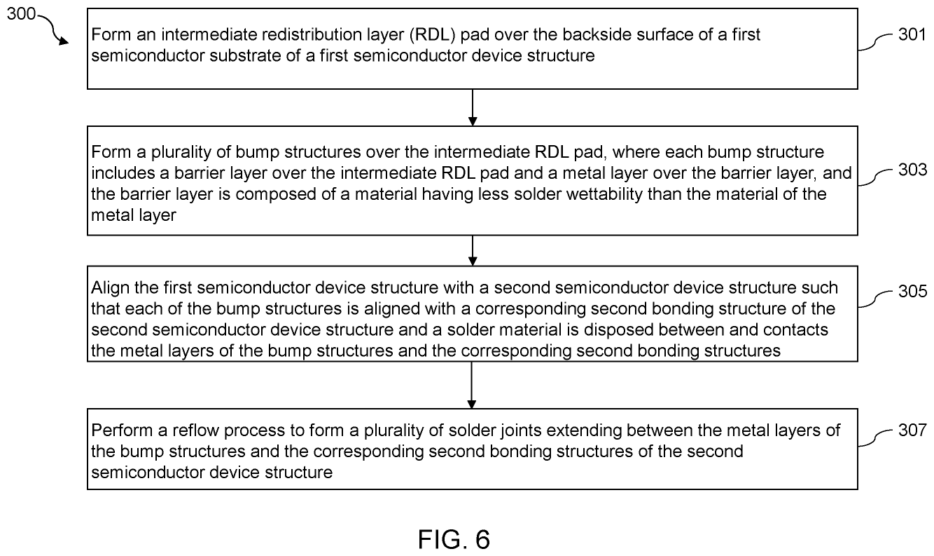

FIG. 6 is a flowchart illustrating a method 300 of fabricating a vertically stacked semiconductor device 150 according to an embodiment of the present disclosure. Referring to FIGS. 1A, 1B and 6, in step 301 of method 300, an intermediate redistribution layer (RDL) pad 103 may be formed over the backside surface 132 of a first semiconductor substrate 102 of a first semiconductor device structure 101. Referring to FIGS. 1A, 1B and 6, in step 303 of method 300, a plurality of bump structures 106 may be formed over the intermediate RDL pad 103, where each bump structure 106 may include a barrier layer 104 over the intermediate RDL pad 103 and a metal layer 105 over the barrier layer 104, and the barrier layer 104 is composed of a material having less solder wettability than the material of the metal layer 105. Referring to FIGS. 1E, 2A and 6, in step 305 of method 300, the first semiconductor device structure 101 may be aligned with a second semiconductor device structure 201 such that each of the bump structures 106 is aligned with a corresponding second bonding structure 205 of the second semiconductor device structure 201 and a solder material 107, 214 is disposed between and contacts the metal layers 105 of the bump structures 106 and the corresponding second bonding structures 205. Referring to FIGS. 1F, 2B and 6, in step 307 of method 300, a reflow process may be performed to form a plurality of solder joints 109 extending between the bump structures 106 and the corresponding second bonding structures 205 of the second semiconductor device structure 201.

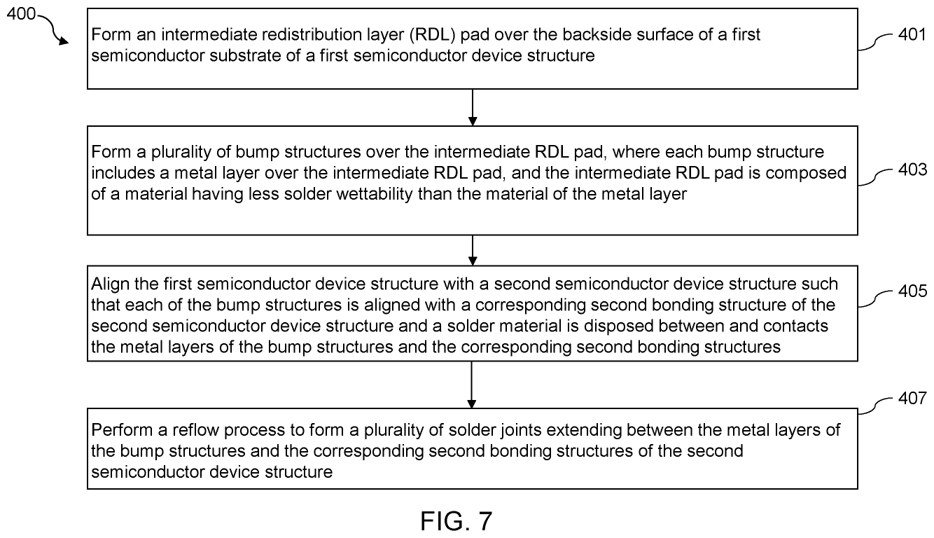

FIG. 7 is a flowchart illustrating a method 400 of fabricating a vertically stacked semiconductor device 150 according to another embodiment of the present disclosure. Referring to FIGS. 3A and 7, in step 401 of method 400, an intermediate redistribution layer (RDL) pad 103 may be formed over the backside surface 132 of a first semiconductor substrate 102 of a first semiconductor device structure 101. Referring to FIGS. 3A and 7, in step 403 of method 400, a plurality of bump structures 106 may be formed over the intermediate RDL pad 103, where each bump structure 106 includes a metal layer 105 over the intermediate RDL pad 103, and the intermediate RDL pad 103 is composed of a material having less solder wettability than the material of the metal layer 105. Referring to FIGS. 3A and 7, in step 405 of method 400, the first semiconductor device structure 101 may be aligned with a second semiconductor device structure 201 such that each of the bump structures 106 is aligned with a corresponding second bonding structure 205 of the second semiconductor device structure 201 and a solder material 107 is disposed between and contacts the metal layers 105 of the bump structures 106 and the corresponding second bonding structures 205. Referring to FIGS. 3B and 7, in step 407 of method 500, a reflow process may be performed to form a plurality of solder joints 109 extending between the bump structures 106 and the corresponding second bonding structures 205 of the second semiconductor device structure 201.

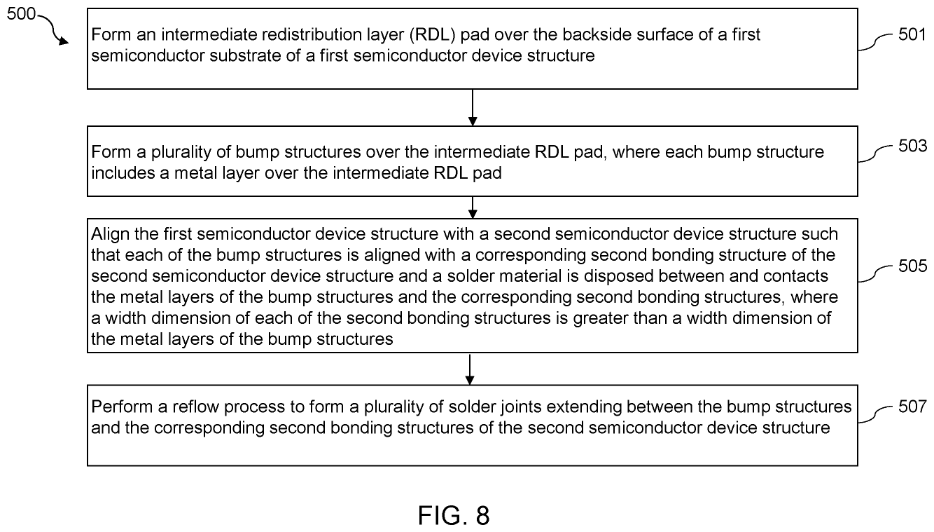

FIG. 8 is a flowchart illustrating a method 500 of fabricating a vertically stacked semiconductor device 150 according to another embodiment of the present disclosure. Referring to FIGS. 4A and 8, in step 501 of method 500, an intermediate redistribution layer (RDL) pad 103 may be formed over the backside surface 132 of a first semiconductor substrate 102 of a first semiconductor device structure 101. Referring to FIGS. 4A and 8, in step 503 of method 500, a plurality of bump structures 106 may be formed over the intermediate RDL pad 103, where each bump structure 106 includes a metal layer 105 over the intermediate RDL pad 103. Referring to FIGS. 4A and 8, in step 505 of method 400, the first semiconductor device structure 101 may be aligned with a second semiconductor device structure 201 such that each of the bump structures 106 is aligned with a corresponding second bonding structure 205 of the second semiconductor device structure 201 and a solder material 107 is disposed between and contacts the metal layers 105 of the bump structures 106 and the corresponding second bonding structures 205, where a width dimension of each of the second bonding structures 205 is greater than a width dimension of the metal layers 105 of the bump structures 106. Referring to FIGS. 4B and 8, in step 507 of method 500, a reflow process may be performed to form a plurality of solder joints 109 extending between the bump structures 106 and the corresponding second bonding structures 205 of the second semiconductor device structure 201.

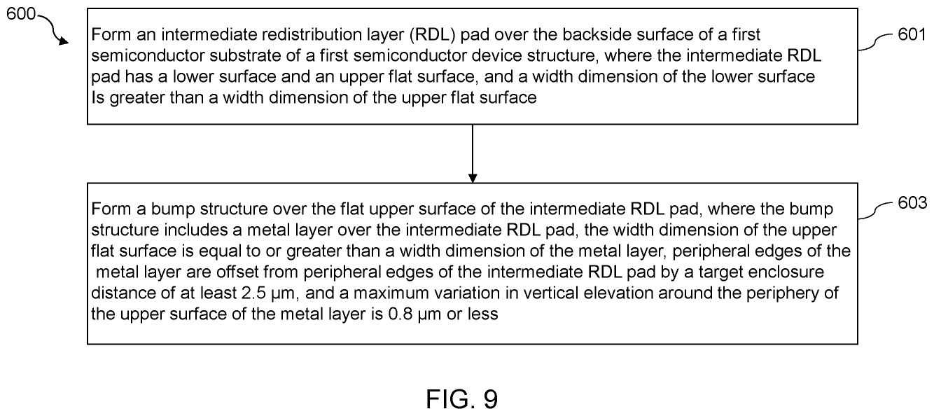

FIG. 9 is a flowchart illustrating a method 600 of fabricating a bonding structure according to another embodiment of the present disclosure. Referring to FIGS. 5A, 5B and 9, in step 601 of method 600, an intermediate redistribution layer (RDL) pad 103 may be formed over the backside surface of a first semiconductor substrate 102 of a first semiconductor device structure 101, where the intermediate RDL pad 103 has a lower surface 161 and an upper flat surface 162, and a width dimension 121 of the lower surface 161 is greater than a width dimension 123 of the upper flat surface 162. Referring to FIGS. 5A, 5B and 9, in step 603 of method 600, a bump structure 106 may be formed over the flat upper surface 162 of the intermediate RDL pad 103, where the bump structure 106 includes a metal layer 105 over the intermediate RDL pad 103, the width dimension 123 of the upper flat surface 162 is equal to or greater than a width dimension 125 of the metal layer 105, peripheral edges of the metal layer 105 are offset from peripheral edges of the intermediate RDL pad 103 by a target enclosure distance 127 of at least 2.5 μm, and a maximum variation in vertical elevation around the periphery of the upper surface 159 of the metal layer 105 is 0.8 μm or less.

Referring to all drawings and according to various embodiments of the present disclosure, a semiconductor device 150 includes a first device structure 101 including a first semiconductor substrate 102, an intermediate redistribution layer (RDL) pad 103, a plurality of bump structures 106 electrically connected to the intermediate RDL pad 103, where the intermediate RDL pad 103 is located between the first semiconductor substrate 102 and the plurality of bump structures 106, and each of the bump structures 106 includes a metal layer 105 and a barrier layer 104 located between the metal layer 105 and the intermediate RDL pad 103, and the solder wettability of the metal layer 105 is greater than the solder wettability of the barrier layer 105, a second device structure 201 including a second semiconductor substrate 202 and second bonding structures 205, and a plurality solder joints 109 disposed between the metal layers 105 of the bump structures 106 of the first device structure 101 and the second bonding structures 205 of the second device structure 201.

In one embodiment, the first device structure 101 includes a plurality of through-substrate vias (TSVs) 112 extending through the first semiconductor substrate 102, the intermediate RDL pad 103 is located over a backside surface 132 of the first semiconductor substrate 102 and electrically contacts at least one of the TSVs 112.

In another embodiment, the intermediate RDL pad 103 includes a first intermediate RDL pad 103a, and the first device structure 102 further includes a second intermediate RDL pad 103b located over the backside surface 132 of the first semiconductor substrate 102 and electrically contacting at least one of the TSVs 112, and at least one bump structure 106 electrically contacting the second intermediate RDL pad 103b and coupled to a corresponding second bonding structure 205 of the second device structure 201 via a solder joint 109, where at least one of the size or shape of the first intermediate RDL pad 103a is different than a corresponding size or shape of the second intermediate RDL pad 103b, a total number of bump structures 106 electrically contacting the first intermediate RDL pad 103a is different than the total number of bump structures 106 electrically contacting the second intermediate RDL pad 103b, and the plurality of bump structures 106 electrically contacting the first intermediate RDL pad 103a and the at least one bump structure 106 electrically contacting the second intermediate RDL pad 103b have the same critical dimensions.

In another embodiment, the plurality of bump structures 106 electrically contacting the first intermediate RDL pad 103a transmits signals of a first type between the first device structure 101 and the second device structure 201, and the at least one bump structure 106 electrically contacting the second intermediate RDL pad 103b transmits signals of a second type between the first device structure 101 and the second device structure 201.

In another embodiment, the signals of the first type include power signals, and the signals of the second type include data signals.

In another embodiment, the metal layers 105 of the bump structures 106 include at least one of copper (Cu), palladium (Pd), rhodium (Rh), gold (Au), and silver (Ag), including alloys and combinations thereof, and the barrier layers 104 of the bump structures 106 include at least one of nickel (Ni), iron (Fe), and tungsten (W), including alloys and combinations thereof.

In another embodiment, the metal layers 105 of the bump structures 106 and the intermediate RDL pad 103 are formed of the same material.

In another embodiment, a width dimension of the barrier layers 104 of the bump structures 106 is greater than a width dimension of the metal layers 105 of the bump structures 106.

In another embodiment, each of the second bonding structures 205 includes a barrier layer 212 located between a pair of metal portions 211, 213, and the solder wettability of the pair of metal portions 211, 213 is greater than the solder wettability of the barrier layer 212 in the second bonding structures 205.

In another embodiment, a thickness of the barrier layers 104 of the bump structures 106 is equal to or greater than the thickness of the barrier layers 212 of the second bonding structures 205.

In another embodiment, each of the second bonding structures 205 includes a metal portion, and a width dimension of the metal layers of the second bonding structures 205 is greater than a width dimension of the metal layers 105 of the bump structures 106.

In another embodiment, each of the metal layers 105 of the bump structures 106 includes an upper surface 159 that contacts the solder joint 109, and a maximum variation in vertical elevation around a periphery of the upper surface 159 of the bump structures 106 is 0.8 μm or less.

Another embodiment is drawn to a semiconductor device 150 that includes a first device structure 101 including a first semiconductor substrate 102, an intermediate redistribution layer (RDL) pad 103, a plurality of bump structures 106 electrically connected to the intermediate RDL pad 103, where the intermediate RDL pad 103 is located between the first semiconductor substrate 102 and the plurality of bump structures 106, and each of the bump structures 106 includes a metal layer 105, and the solder wettability of the metal layer 105 of the bump structures 106 is greater than the solder wettability of the intermediate RDL pad 103, a second device structure 201 including a second semiconductor substrate 202 and second bonding structures 205, and a plurality solder joints 109 disposed between the metal layers 105 of the bump structures 106 of the first device structure 101 and the second bonding structures 205 of the second device structure 201.

In one embodiment, the metal layers of the bump structures 106 include at least one of copper (Cu), palladium (Pd), rhodium (Rh), gold (Au), and silver (Ag), including alloys and combinations thereof, and the intermediate RDL pad 103 includes at least one of nickel (Ni), iron (Fe), and tungsten (W), including alloys and combinations thereof.

In another embodiment, each of the bump structures 106 includes a barrier layer 104 between the metal layer 105 and the intermediate RDL pad 103, and the composition of the barrier layer 104 is different than the composition of the metal layer 105.

Another embodiment is drawn to a method of fabricating a vertically stacked semiconductor device 150 that includes forming an intermediate redistribution layer (RDL) pad 103 over a backside surface 132 of a first semiconductor substrate 102 of a first semiconductor device structure 101, forming a plurality of bump structures 106 over the intermediate RDL pad 103, where each bump structure 106 includes a barrier layer 104 over the intermediate RDL pad 103 and a metal layer 105 over the barrier layer 104, and the barrier layer 104 comprises a material having less solder wettability than the material of the metal layer 105, aligning the first semiconductor device structure 101 with a second semiconductor device structure 201 such that each of the bump structures 106 is aligned with a corresponding second bonding structure 205 of the second semiconductor device structure 201 and a solder material 107 is disposed between the metal layers 105 of the bump structures 106 and the corresponding second bonding structures 205, and performing a reflow process to form a plurality of solder joints 109 extending between the bump structures 106 and the corresponding second bonding structures 205 of the second semiconductor device structure 201.

In one embodiment, the method further includes providing a solder material layer 107 over each of the metal layers 105 of the bump structures 106, and where each of the second bonding structures 205 includes a metal portion, aligning the first semiconductor device structure 101 with the second semiconductor device structure 201 includes bringing the solder material layers 107 and the metal portions of the second bonding structures 205 into contact with one another, the metal layers 105 of the bump structures 106 have a first thickness T1, the metal portions of the second bonding structures 205 have a second thickness T2, and the solder material layers 107 have a third thickness T3, and a sum of the first thickness T1 and the second thickness T2 is equal to or greater than one half of the third thickness T3.

In another embodiment, the method further includes providing a first solder material layer 107 over each of the metal layers 105 of the bump structures 106, and providing a second solder material layer 214 over each of the second bonding structures 205, and where each of the second bonding structures 205 includes a barrier layer 212 located between a pair of metal portions 211, 213, aligning the first semiconductor device structure 101 with the second semiconductor device structure 201 includes bringing the first solder material layers 107 and the second solder material layers 214 into contact with one another, a sum of the combined thicknesses of the metal portions 211, 213 in the second bonding structures 205 is equal to or greater than one half of the combined thicknesses of the first solder material layer 107 and the second solder material layer 214, and the thickness of the barrier layers 104 of the bump structures 106 is equal to or greater than the thickness of the barrier layers 212 of the second bonding structures 205.

In another embodiment, a plurality of intermediate RDL pads 103 having different sizes or shapes are formed over the backside surface 132 of the first semiconductor substrate 102, and at least one bump structure 106 is formed over each of the intermediate RDL pads 103, and all of the bump structures 106 formed over the intermediate RDL pads 103 have the same size and shape.

In another embodiment, the intermediate RDL pads 103 and the bump structures 106 are formed via electroplating.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor device, comprising:
a first device structure comprising:
a first semiconductor substrate;
an intermediate redistribution layer (RDL) pad; and
a plurality of bump structures electrically connected to the intermediate RDL pad, wherein the intermediate RDL pad is located between the first semiconductor substrate and the plurality of bump structures, and each of the plurality of bump structures comprises:
a metal layer; and
a barrier layer, wherein the barrier layer is located between the metal layer and the intermediate RDL pad, and a solder wettability of the metal layer is greater than a solder wettability of the barrier layer;
a second device structure comprising a second semiconductor substrate and second bonding structures; and
a plurality of solder joints disposed between the metal layers of the bump structures of the first device structure and the second bonding structures of the second device structure.

2. The semiconductor device of claim 1, wherein the first device structure comprises a plurality of through-substrate vias (TSVs) extending through the first semiconductor substrate, the intermediate RDL pad is located over a backside surface of the first semiconductor substrate and electrically contacts at least one of the TSVs.

3. The semiconductor device of claim 2, wherein the intermediate RDL pad comprises a first intermediate RDL pad, and the first device structure further comprises:
a second intermediate redistribution layer (RDL) pad located over the backside surface of the first semiconductor substrate and electrically contacting at least one of the TSVs; and
at least one bump structure electrically contacting the second intermediate RDL pad and coupled to a corresponding second bonding structure of the second device structure via a solder joint, wherein:
at least one of the size or shape of the first intermediate RDL pad is different than a corresponding size or shape of the second intermediate RDL pad;
a total number of bump structures electrically contacting the first intermediate RDL pad is different than the total number of bump structures electrically contacting the second intermediate RDL pad; and
the plurality of bump structures electrically contacting the first intermediate RDL pad and the at least one bump structure electrically contacting the second intermediate RDL pad have the same critical dimensions.

4. The semiconductor device of claim 3, wherein the plurality of bump structures electrically contacting the first intermediate RDL pad transmits signals of a first type between the first device structure and the second device structure, and the at least one bump structure electrically contacting the second intermediate RDL pad transmits signals of a second type between the first device structure and the second device structure.

5. The semiconductor device of claim 4, wherein the signals of the first type comprise power signals, and the signals of the second type comprise data signals.

6. The semiconductor device of claim 1, wherein the metal layers the plurality of bump structures comprise at least one of copper (Cu), palladium (Pd), rhodium (Rh), gold (Au), and silver (Ag), including alloys or combinations thereof, and the barrier layers of the bump structures comprise at least one of nickel (Ni), iron (Fe), and tungsten (W), including alloys or combinations thereof.

7. The semiconductor device of claim 6, wherein the metal layers of each of the plurality of bump structures and the intermediate RDL pad are formed of a same material.

8. The semiconductor device of claim 1, wherein a width dimension of the barrier layers of the bump structures is greater than a width dimension of the metal layers of each of the plurality of bump structures.

9. The semiconductor device of claim 1, wherein each of the second bonding structures comprises a barrier layer located between a pair of metal portions, and the solder wettability of the pair of metal portions is greater than the solder wettability of the barrier layer in the second bonding structures.

10. The semiconductor device of claim 1, wherein a thickness of the barrier layers of each of the plurality of bump structures is equal to or greater than the thickness of the barrier layers of the second bonding structures.

11. The semiconductor device of claim 1, wherein each of the second bonding structures comprises a metal portion, and a width dimension of the metal portion of the second bonding structures is greater than a width dimension of the metal layers of each of the plurality of bump structures.

12. The semiconductor device of claim 3, wherein each of the metal layers of each of the plurality of bump structures comprises an upper surface that contacts the solder joint, and a maximum variation in vertical elevation around a periphery of the upper surface of each of the plurality of bump structures is 0.8 μm or less.

13. A semiconductor device, comprising:
a first device structure comprising:
a first semiconductor substrate;
an intermediate redistribution layer (RDL) pad; and
a plurality of bump structures electrically connected to the intermediate RDL pad, wherein the intermediate RDL pad is located between the first semiconductor substrate and the plurality of bump structures, and each of the plurality of bump structures comprises a metal layer, and the solder wettability of the metal layer of each of the plurality of bump structures is greater than the solder wettability of the intermediate RDL pad;
a second device structure comprising a second semiconductor substrate and second bonding structures; and
a plurality of solder joints disposed between the metal layers of each of the plurality of bump structures of the first device structure and the second bonding structures of the second device structure.

14. The semiconductor device of claim 13, wherein the metal layers the plurality of bump structures comprise at least one of copper (Cu), palladium (Pd), rhodium (Rh), gold (Au), and silver (Ag), including alloys or combinations thereof, and the intermediate RDL pad comprises at least one of nickel (Ni), iron (Fe), and tungsten (W), including alloys or combinations thereof.

15. The semiconductor device of claim 13, wherein each of the plurality of bump structures comprises a barrier layer between the metal layer and the intermediate RDL pad, and the composition of the barrier layer is different than the composition of the metal layer.

16. A semiconductor device, comprising:
a first device structure comprising:
a first semiconductor substrate;
an intermediate redistribution layer (RDL) pad having a lower surface and a flat upper surface, wherein a width dimension of the lower surface is greater than a width dimension of the flat upper surface; and
a bump structure over the flat upper surface of the intermediate RDL pad, wherein the bump structure comprises a metal layer having an upper surface, and a maximum variation in vertical elevation around a periphery of the upper surface of the metal layer is 0.8 μm or less;
a second device structure comprising a second semiconductor substrate and a second bonding structure; and
a solder joint disposed between the metal layer of the bump structure of the first device structure and the second bonding structure of the second device structure.

17. The semiconductor device of claim 16, wherein peripheral edges of the metal layer are offset from peripheral edges of the intermediate RDL pad by an enclosure distance of at least 2.5 μm.

18. The semiconductor device of claim 16, wherein the width dimension of the flat upper surface is equal to or greater than a width dimension of the metal layer.

19. The semiconductor device of claim 16, wherein the bump structure further comprises a barrier layer located between the metal layer and the intermediate RDL pad, and a solder wettability of the metal layer is greater than a solder wettability of the barrier layer.

20. The semiconductor device of claim 16, wherein the first device structure comprises a plurality of through-substrate vias extending through the first semiconductor substrate, and the intermediate RDL pad electrically contacts at least one of the through-substrate vias.
